(19) United States
(12) Patent Application Publication
(10) Pub. No.: US 2014/0374744 A1
(43) Pub. Date: Dec. 25, 2014

(54) SEMICONDUCTOR DEVICE

(71) Applicant: Semiconductor Energy Laboratory Co., Ltd., Atsugi-shi (JP)

(72) Inventor: Hideki MATSUKURA, Atsugi (JP)

(21) Appl. No.: 14/302,852

(22) Filed: Jun. 12, 2014

(30) Foreign Application Priority Data
Jun. 19, 2013 (JP) 2013-128068

(51) Int. Cl. H01L 27/088; H01L 29/24

(52) U.S. Cl. CPC H01L 27/088; H01L 29/24
USPC 257/43

(57) ABSTRACT

To provide a new layout. A semiconductor device includes a first conductive layer; a first insulating layer over the first conductive layer; an oxide semiconductor layer over the first insulating layer; a second conductive layer electrically connected to the oxide semiconductor layer; a third conductive layer electrically connected to the oxide semiconductor layer; a fourth conductive layer over the first insulating layer; a second insulating layer over the oxide semiconductor layer, the second conductive layer, the third conductive layer, and the fourth conductive layer; a fifth conductive layer over the second insulating layer; a first opening in the first and second insulating layers; and a second opening in the second insulating layer.

### BACKGROUND OF THE INVENTION

1. Field of the Invention

The technical field relates to semiconductor devices and the like.

2. Description of the Related Art

An improvement of a layout is a perennial issue.

For example, a semiconductor device having a new layout is disclosed in Patent Document 1.

The layout of two transistors is disclosed in Patent Document 1.

The concept of Patent Document I is to place one of the two transistors over the other of the two transistors.

### REFERENCE

[Patent Document 1] Japanese Published Patent Application No. 2013-012730

### SUMMARY OF THE INVENTION

The concept of Patent Document 1 is excellent, but the number of processes is increased.

An object is to provide a new layout based on a concept that is different from the concept of Patent Document 1.

### (Basic Elements of Transistor)

A transistor has at least a first gate electrode; a first insulating layer over the first gate electrode; a semiconductor layer over the first insulating layer; a source electrode electrically connected to the semiconductor layer; and a drain electrode electrically connected to the semiconductor layer.

### (Basic Elements of Circuit)

The first gate electrode of a first transistor is electrically connected to one of a source electrode and a drain electrode of a second transistor.

Note that an ordinal number is added to “transistor” to distinguish the two transistors.

### (One Example of Concept)

A second insulating layer is placed over a semiconductor layer of the first transistor, the source electrode of the first transistor, the drain electrode of the first transistor, a semiconductor layer of the second transistor, the source electrode of the second transistor, and the drain electrode of the second transistor.

A conductive layer is formed over the second insulating layer.

The first insulating layer has a first opening.

The second insulating layer has a second opening and a third opening.

The conductive layer is electrically connected to the first gate electrode of the first transistor through the first opening and second opening.

The conductive layer is electrically connected to one of the source electrode and the drain electrode of the second transistor through the third opening.

The conductive layer has a region overlapping with a channel formation region of the first transistor.

The conductive layer has at least two functions.

One of the two functions is a connection electrode.

The other of the two functions is a second gate electrode of the first transistor.

Because the first transistor has two gate electrodes, the electrical property of the first transistor is good. For example, the mobility of the first transistor having the two gate electrodes is high.

The electrical property of the first transistor is improved by devising the layout of the connection electrode.

In other words, one example of a new layout is to place the connection electrode over the channel formation region of the first transistor with the second insulating layer placed therebetween.

### (Transistor Having Oxide Semiconductor Layer (OS-FET))

There are no particular limitations on the semiconductor layer of the transistor, but the use of an oxide semiconductor layer as the semiconductor layer is of interest.

The reason why it is of interest is explicit from this specification itself.

### (Examples of Invention Disclosed)

For example, an embodiment of the present invention is a semiconductor device including a first conductive layer; a first insulating layer over the first conductive layer; an oxide semiconductor layer over the first insulating layer; a second conductive layer electrically connected to the oxide semiconductor layer; a third conductive layer electrically connected to the oxide semiconductor layer; a fourth conductive layer over the first insulating layer; a second insulating layer over the oxide semiconductor layer, the second conductive layer, the third conductive layer, and the fourth conductive layer; and a fifth conductive layer over the second insulating layer. In the semiconductor device, the first insulating layer has a first opening, the second insulating layer has a second opening, the second insulating layer has a third opening, the fifth conductive layer is electrically connected to the first conductive layer in the first opening and the second opening, the fifth conductive layer is electrically connected to the fourth conductive layer in the third opening, the fourth conductive layer includes a first region capable of functioning as one of a source electrode and a drain electrode of a transistor, and the oxide semiconductor layer includes a second region overlapping with the first conductive layer and the fifth conductive layer.

For example, an embodiment of the present invention is a semiconductor device including a first conductive layer; a first insulating layer over the first conductive layer; an oxide semiconductor layer over the first insulating layer; a second conductive layer electrically connected to the oxide semiconductor layer; a third conductive layer electrically connected to the oxide semiconductor layer; a fourth conductive layer over the first insulating layer; a sixth conductive layer over the first insulating layer; a second insulating layer over the oxide semiconductor layer, the second conductive layer, the third conductive layer, and the fourth conductive layer; and a fifth conductive layer over the second insulating layer. In the semiconductor device, the first insulating layer has a first opening, the second insulating layer has a second opening, the second insulating layer has a third opening, the sixth conductive layer is electrically connected to the first conductive layer in the first opening, the fifth conductive layer is electrically connected to the sixth conductive layer in the second opening, the fifth conductive layer is electrically connected to the fourth conductive layer in the third opening, the fourth conductive layer includes a first region capable of functioning as one of a source electrode and a drain electrode of a transistor, and the oxide semiconductor layer includes a second region overlapping with the first conductive layer and the fifth conductive layer.

For example, the second opening does not overlap with the first opening.

For example, the semiconductor device includes an oxide layer between the oxide semiconductor layer and the second insulating layer. The first conductive layer includes a third region not overlapping with the oxide layer, and the fifth conductive layer includes a fourth region overlapping with the third region.

A new layout based on a concept different from that of conventional art can be provided.

### BRIEF DESCRIPTION OF THE DRAWINGS

FIGS. 1A to 1C is an example of a semiconductor device.

FIG. 2 is an example of a semiconductor device.

FIG. 3 is an example of a semiconductor device.

FIGS. 4A to 4C is an example of a semiconductor device.

FIGS. 5A to 5C is an example of a semiconductor device.

FIGS. 6A to 6C is an example of a semiconductor device.

FIGS. 7A to 7C is an example of a semiconductor device.

FIGS. 8A to 8C is an example of a semiconductor device.

FIGS. 9A to 9C is an example of a semiconductor device.

FIGS. 10A to 10C is an example of a semiconductor device.

FIGS. 11A to 11C is an example of a semiconductor device.

FIGS. 12A to 12C is an example of a semiconductor device.

FIGS. 13A to 13C is an example of a semiconductor device.

FIGS. 14A to 14C is an example of a semiconductor device.

FIGS. 15A to 15C is an example of a semiconductor device.

FIGS. 16A to 16C is an example of a semiconductor device.

FIGS. 17A to 17C is an example of a semiconductor device.

FIGS. 18A to 18C is an example of a semiconductor device.

FIGS. 19A to 19F are examples of semiconductor devices.

FIG. 20 is an example of a semiconductor device.

FIG. 21 is an example of a semiconductor device.

FIG. 22 is an example of a semiconductor device.

FIG. 23 is an example of a semiconductor device.

FIG. 24 is an example of a semiconductor device.

FIG. 25 is an example of a semiconductor device.

FIG. 26 is an example of a semiconductor device.

### DETAILED DESCRIPTION OF THE INVENTION

Embodiments will be described in detail with reference to drawings as needed.

Contents described in the embodiments are each just one example.

It will be easily understood by those skilled in the art that modes and details of the present invention can be modified without departing from the spirits of the present invention.

Therefore, the present invention should not be construed as being limited to description of the embodiments.

In the embodiments, portions show e same reference numerals are not explained repeatedly.

In the embodiments and drawings, it is noted that the same reference numerals are used for like potions or potions having like functions.

Furthermore, the contents described in the embodiments can be combined with one another.

### Embodiment 1

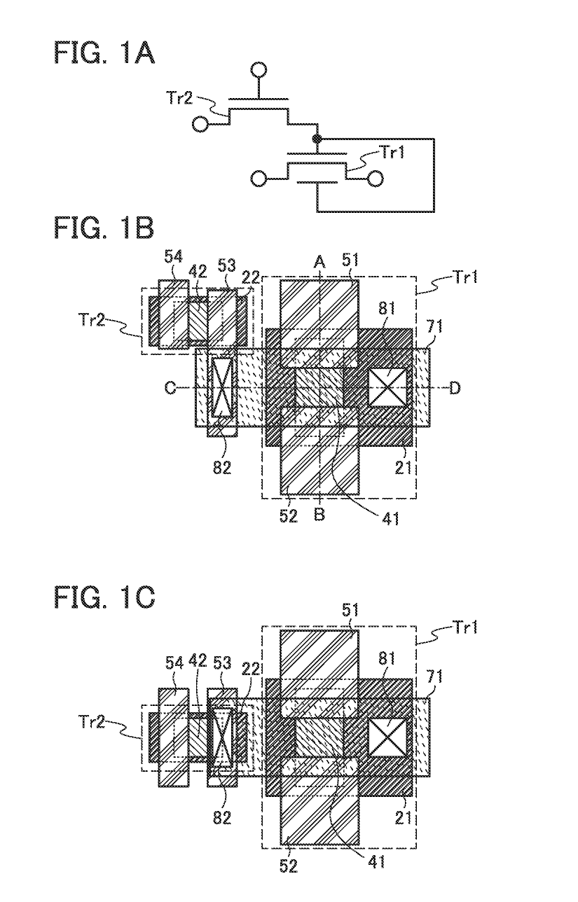

A semiconductor device is shown in FIGS. 1A to 1C, FIG. 2, and FIG. 3.

FIG. 1A is an example of a component in a circuit.

FIG. 1B is a top view illustrating an example of the layout.

FIG. 1C is a top view illustrating another example of the layout.

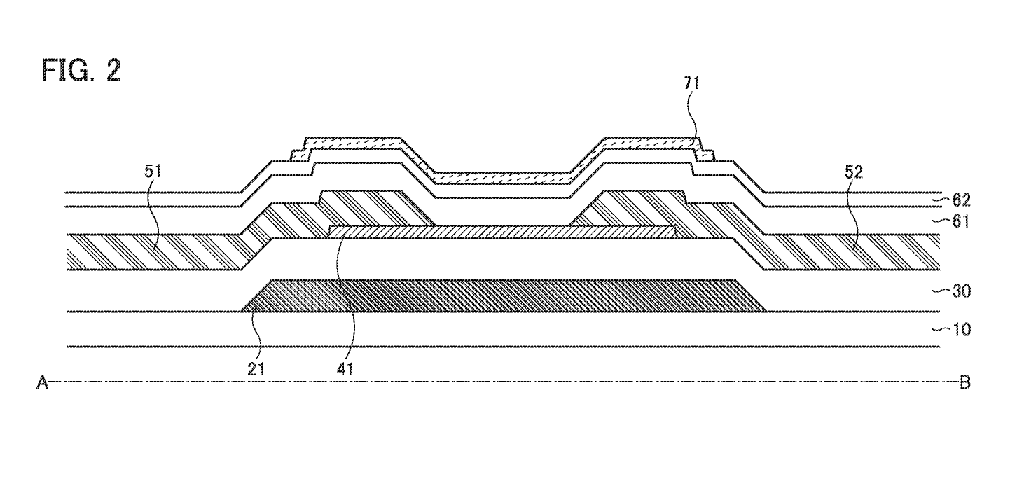

FIG. 2 is one example of a cross section taken along the line A-B in FIG. 1B.

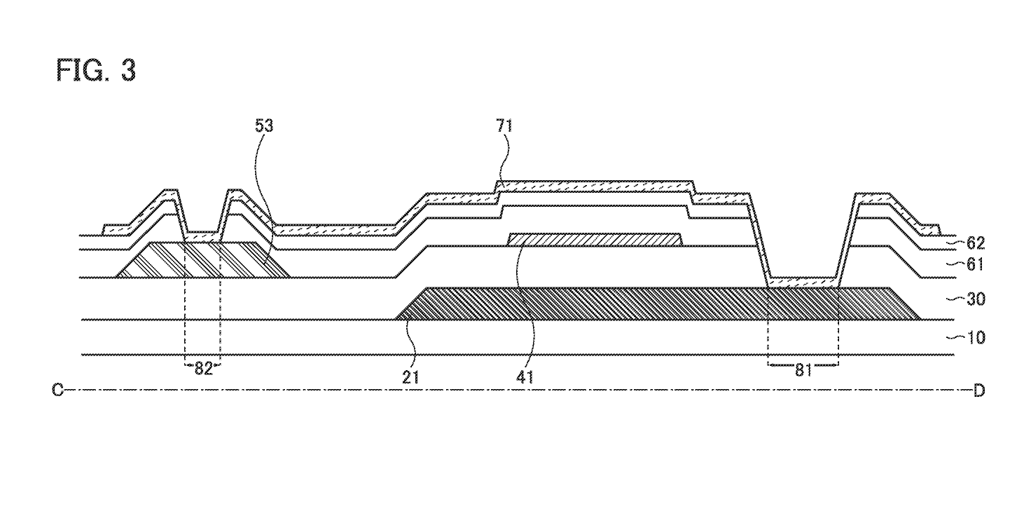

FIG. 3 is one example of a cross section taken along the line C-D in FIG. 1B.

In FIG. 1A, one of a source electrode and a drain electrode of a transistor Tr2 is electrically connected to a first gate electrode of a transistor Tr1

In FIG. 1A, the one of the source electrode and the drain electrode of the transistor Tr2 is electrically connected to a second gate electrode of the transistor Tr1.

The following will be described with reference to FIGS. 1A to 1C, FIG. 2, and FIG. 3.

### <Conductive Layers 21, 22>

A conductive layer 21 is placed over a substrate 10.

A conductive layer 22 is placed over the substrate 10.

The conductive layer 21 has a region capable of functioning as the first gate electrode of the transistor Tr1.

The conductive layer 22 has a region capable of functioning as a gate electrode of the transistor Tr2.

For example, the conductive layer 21 and the conductive layer 22 can be formed through a process of etching the same conductive layer.

In FIG. 2 and FIG. 3, the conductive layer 21 is in contact with the substrate 10, but it is possible to form an insulating layer having a function of a base insulating layer between the substrate 10 and the conductive layer 21.

### <Insulating Layer 30>

An insulating layer 30 is placed over the conductive layer 21 and the conductive layer 22.

The insulating layer 30 has a region capable of functioning as a gate insulating layer of the transistor Tr1

The insulating layer 30 has a region capable of functioning as a gate insulating layer of the transistor Tr2.

### <Semiconductor Layers 41, 42>

A semiconductor layer 41 is placed over the insulating layer 30.

A semiconductor layer 42 is placed over the insulating layer 30.

The semiconductor layer 41 has a region overlapping with the conductive layer 21.

The semiconductor layer 42 has a region overlapping with the conductive layer 22.

The semiconductor layer 41 has a channel formation region of the transistor Tr1.

The semiconductor layer 42 has a channel form anon region of the transistor Tr2.

Preferably, each of the semiconductor layer 41 and the semiconductor layer 42 is an oxide semiconductor, because the off-state current of the transistors Tr1 and Tr2 is reduced.

For example, e semiconductor layer 41 and the semiconductor layer 42 can be formed through a process of etching the same semiconductor layer.

### <Conductive Layers 51, 52, 53, 54>

A conductive layer 51 electrically connected to the semiconductor layer 41 is placed over the insulating layer 30 and the semiconductor layer 41.

A conductive layer 52 electrically connected to the semiconductor layer 41 is placed over the insulating layer 30 and the semiconductor layer 41.

A conductive layer 53 electrically connected to the semiconductor layer 42 is placed over the insulating layer 30 and the semiconductor layer 42.

A conductive layer 54 electrically connected to the semiconductor layer 42 is placed over the insulating layer 30 and the semiconductor layer 42.

The conductive layer 51 has a region overlapping with the semiconductor layer 41.

The conductive layer 52 has a region overlapping with the semiconductor layer 41.

The conductive layer 53 has a region overlapping with the semiconductor layer 42.

The conductive layer 54 has a region overlapping with the semiconductor layer 42.

The conductive layer 51 has a region capable of functioning as one of the source electrode and the drain electrode of the transistor Tr1.

The conductive layer 52 has a region capable of functioning as the other of the source electrode and the drain electrode of the transistor Tr1.

The conductive layer 53 has a region capable of functioning as one of the source electrode and the drain electrode of the transistor Tr2.

The conductive layer 54 has a region capable of functioning as the other of the source electrode and the drain electrode of the transistor Tr2.

For example, the conductive layer 51, the conductive layer 52, the conductive layer 53, and the conductive layer 54 can be formed through a process by which a conductive layer is etched.

Note that an overlapping region of a layer placed in a lower side of stacked layers is illustrated by a broken line in the top views in some cases. For example, in FIG. 1B, the semiconductor layer 42 in a region located under the conductive layer 53 is illustrated by a broken line, In addition, a part of the broken line may be omitted.

The transistor Tr1 and the transistor Tr2 of FIGS. 1A to 1C, FIG. 2, and FIG. 3 have top contact structures.

The top contact structure is a structure where the source electrode and the drain electrode is placed over the semiconductor layer.

For example, the source electrode and the drain electrode are preferably in contact with the top surface of the semiconductor layer.

However, the structures of the transistor Tr1 and the transistor Tr2 are not limited to the top contact structure.

For example, bottom contact structures can be applied to the transistor Tr1 and the transistor Tr2.

The bottom contact structure is a structure where the source electrode and the drain electrode are placed under the semiconductor layer.

In the top contact structure and the bottom contact structure, each of the source electrode and the drain electrode is electrically connected to the semiconductor layer.

### <Oxide Layer 61 and Insulating Layer 62>

An oxide layer 61 is placed over the semiconductor layer 41, the semiconductor layer 42, the conductive layer 51, the conductive layer 52, the conductive layer 53, and the conductive layer 54.

An insulating layer 62 is placed over the oxide layer 61.

The oxide layer 61 is an oxide insulating layer or an oxide semiconductor layer.

It is acceptable not to form the oxide layer 61.

However, when each of the semiconductor layer 41 and the semiconductor layer 42 is an oxide semiconductor, oxygen can be supplied from the oxide layer 61 to each of the semiconductor layer 41 and the semiconductor layer 42.

The oxygen vacancies in the semiconductor layer 41 and the semiconductor layer 42 are decreased by supplying oxygen.

Each of the oxide layer 61 and the insulating layer 62 has a region capable of functioning as a second gate insulating layer of the transistor Tr1.

### <Openings 81, 82>

An opening 81 is formed to penetrate the insulating layer 30, the oxide layer 61, and insulating layer 62 as illustrated in an example of FIG. 3.

The opening 81 has an opening formed in the insulating layer 30, an opening formed in the oxide layer 61, and an opening formed in insulating layer 62.

As illustrated in the example of FIG. 3. an opening 82 is formed to penetrate the oxide layer 61 and insulating layer 62.

The opening 82 has an opening formed in the oxide layer 61 and an opening formed in insulating layer 62.

The conductive layer 21 has a region overlapping with the opening 81.

The conductive layer 53 has a region overlapping with the opening 82.

Each of the opening 81 and the opening 82 has a function of a contact hole.

For example, the opening 81 and the opening 82 can he formed through only one etching step.

### <Conductive Layer 71>

A conductive layer 71 is placed over the insulating layer 62.

The conductive layer 71 is electrically connected to the conductive layer 21 in the opening 81.

The conductive layer 71 is electrically connected to the conductive layer 53 in the opening 82.

The conductive layer 71 has a function of a connection electrode.

The conductive layer 71 has a region overlapping with the semiconductor layer 41.

The conductive layer 71 has a region capable of serving as the second gate electrode of the transistor Tr1.

For example, when the semiconductor device is a display device, the conductive layer 71 and a pixel electrode can be formed through a process of etching the same conductive layer.

For example, when the semiconductor device is a display device, the conductive layer 71 and a common electrode can be formed through a process of etching the same conductive layer.

The pixel electrode is a first electrode of a display element.

The common electrode is a second electrode of the display element.

### <Concept>

The conductive layer 71 has at least two functions.

One of the two functions is a function of a connection electrode.

The other of the two functions is a function of a second gate electrode of the transistor Tr1.

Because the transistor Tr1 has two gate electrodes, the electrical property of the transistor Tr1 is good.

The electrical property of the transistor Tr1 is improved by devising the layout of the connection electrode.

It is possible to consider that “the bridge between the opening 81 and the opening 82 is made of the connection electrode”.

Because the semiconductor layer 41 is placed between the opening 81 and the opening 82, it is possible to consider that “the semiconductor layer 41 is placed under the bridge of the connection electrode”.

Because the opening 81, the semiconductor layer 41, and the opening 82 are placed along a channel width direction of the transistor Tr1, the shape of the conductive layer 71 can be made simple.

For example, in FIGS. 1A to C, the conductive layer 71 is rectangular.

For example, the semiconductor layer 42, the opening 81, the semiconductor layer 41, and the opening 82 can be placed along the channel width direction of the transistor Tr1, in the case where the channel length direction of the transistor Tr1 intersects with the channel length direction of the transistor Tr2.

For example, refer to FIG. 1C.

The layout of FIG. 1C is simpler than the layout of FIG. 1B.

In FIG. 1C, the transistor Tr1 and the transistor Tr2 can be arranged in the area smaller than the area in FIG. 1B.

Because the longer direction of the conductive layer 71 intersects channel length direction of the transistor Tr1, a parasitic capacitance formed between the conductive layer 71 and the conductive layer 51 can be decreased.

For example, the area where the conductive layer 71 and the conductive layer 51 overlap with each other can be decreased.

Because the longer direction of the conductive layer 71 intersects with the channel length direction of the transistor Tr1, a parasitic capacitance formed between the conductive layer 71 and the conductive layer 52 can be decreased.

For example, the area where the conductive layer 71 and the conductive layer 52 overlap with each other can be decreased.

For example, in FIGS. 1A to 1C, the conductive layer 71 has a region not overlapping with the conductive layer 51.

For example, in FIGS. 1A to 1C, the conductive layer 71 has a region not overlapping with the conductive layer 52.

Because the area of an opening is large, the number of the openings is preferably minimum necessary.

Because the number of the openings is increased by increasing the number of the gate electrodes, the number of the gate electrodes of the transistor Tr2 is preferably only one.

A transistor having one gate electrode is called a single gate transistor.

A single gate transistor having a gate electrode under a semiconductor layer is called a bottom gate transistor.

A transistor having two gate electrodes is called a dual gate transistor.

### Embodiment 2

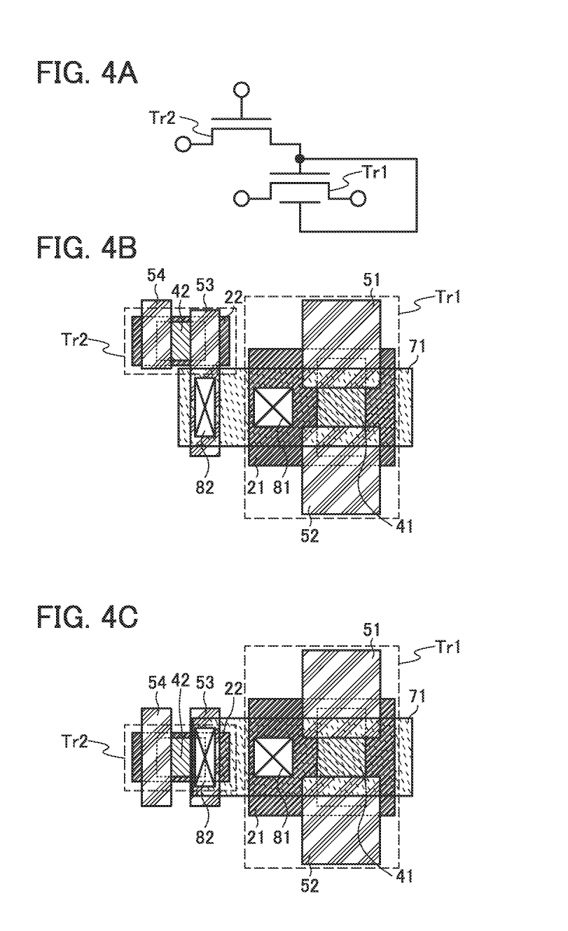

FIGS. 4A to 4C illustrate an exam of a semiconductor device.

In FIGS. 4A to 4C, the opening 81 is located between the opening 82 and semiconductor layer 41.

FIG. 4A is the same as FIG. 1A

FIG. 4B is similar to FIG. 1B, but the position of the opening 81 in FIG. 4B is different from that in FIG. 1B.

FIG. 4C is similar to FIG. 1C, but he position of the opening 81 in FIG. 4C is different from that in FIG. 1C.

In FIGS. 4A to 4C, the opening 81 is closer to the opening 82 in comparison with FIGS. 1A to 1C.

In FIGS. 4A to 4C, the resistance between the opening 81 and the opening 82 is decreased in comparison with FIGS. 1A to 1C.

The contents of Embodiment 1 can be applied to this embodiment.

### Embodiment 3

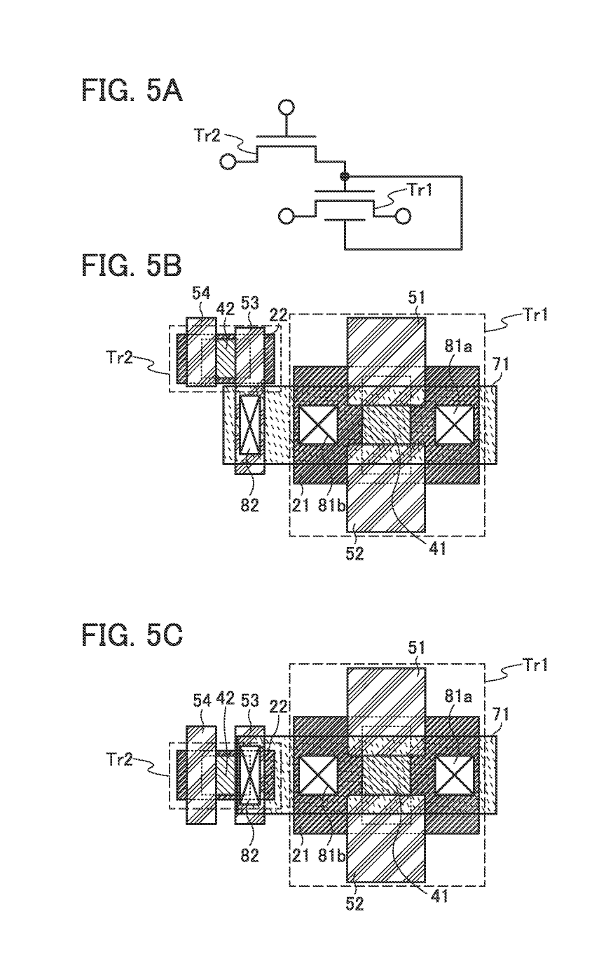

FIGS. 5A to 5C illustrate an example of a semiconductor device.

The semiconductor device illustrated in FIGS. 5A to 5C can include a plurality of openings 81.

In FIGS. 5A to 5C, an opening 81a and an opening 81b are formed.

Cross-sectional structures of the opening 81 a and the opening 81b are similar to that of the opening 81.

In FIGS. 5A to 5C, a semiconductor layer 41 is placed between the opening 81a and the opening 81b.

In FIGS. 5A to 5C, the opening 81b is placed between the opening 82 and semiconductor layer 41.

FIG. 5A is similar to FIG. 1A

FIG. 5B is similar to FIG. 1B, but the number of the opening 81 in FIG. 5B is different from that in FIG. 1B.

FIG. 5C is similar to FIG. 1C, but the number of the opening 81 in FIG. 5C is different from that in FIG. 1C.

In comparison with FIGS. 1A to 1C, the contact resistance can be decreased by increasing the number of the opening 81.

The contents of Embodiments 1 to 2 can be applied to this embodiment.

### Embodiment 4

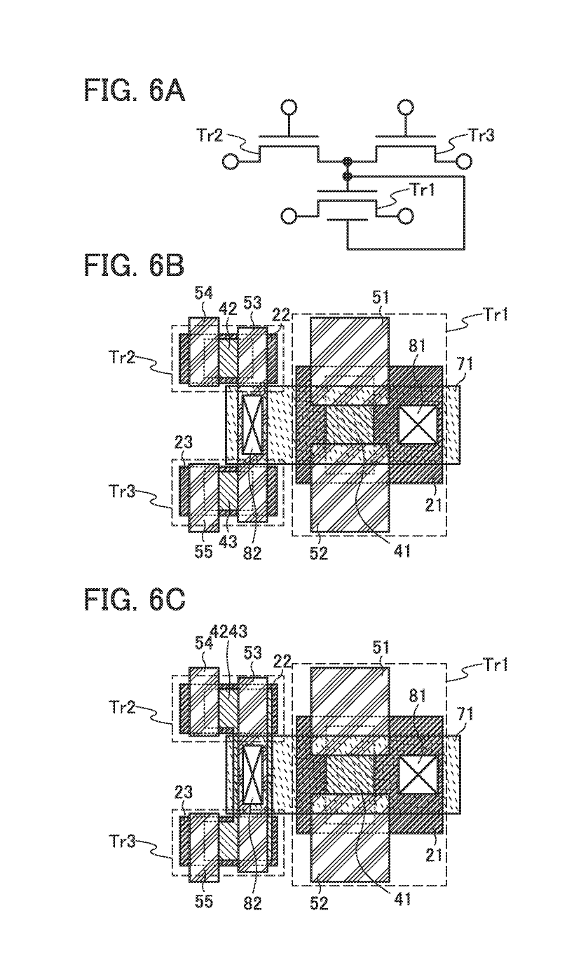

FIGS. 6A to 6C, FIGS. 7A to 7C, FIGS. 8A to 8C, FIGS. 9A to 9C, and FIGS. 10A to 10C each illustrate an example of a semiconductor device.

FIGS. 6A to 6C illustrate an example in which a transistor Tr3 is added to the components in FIGS. 1A to 1C.

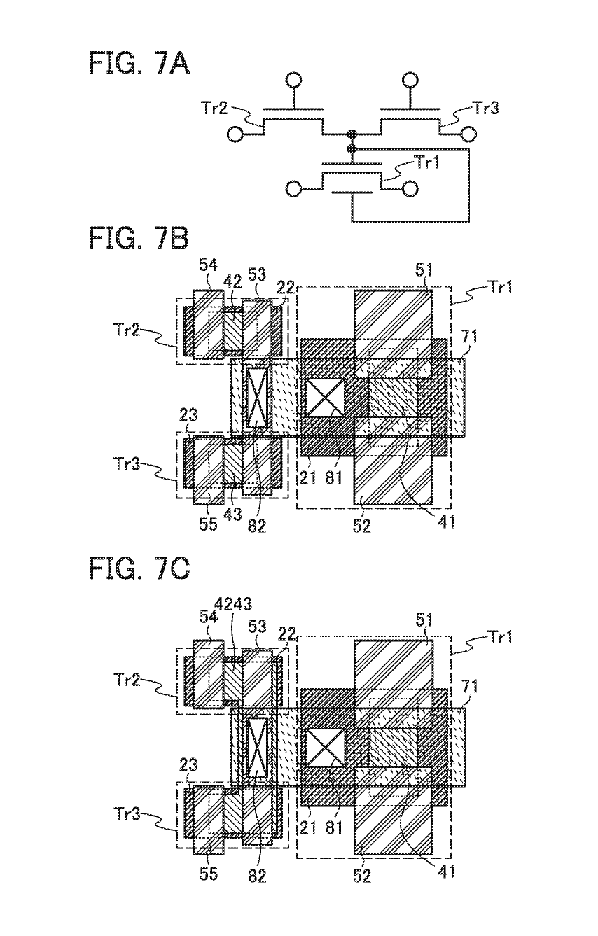

FIGS. 7A to 7C illustrate an example in which a transistor Tr3 is added to the components in FIGS. 4A to 4C.

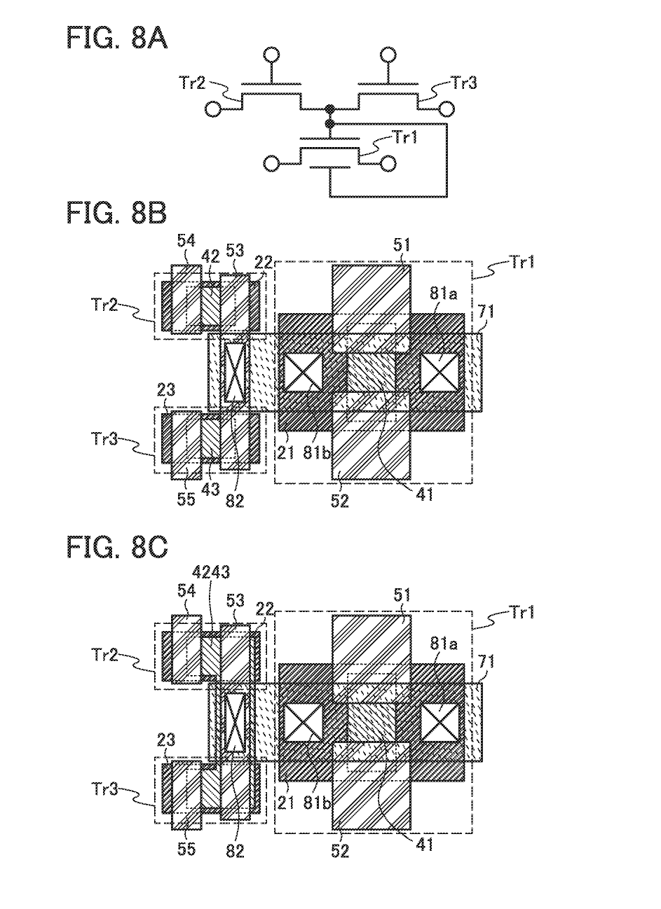

FIGS. 8A to 8C illustrate an example in which a transistor Tr3 is added to the components in FIGS. 5A to 5C.

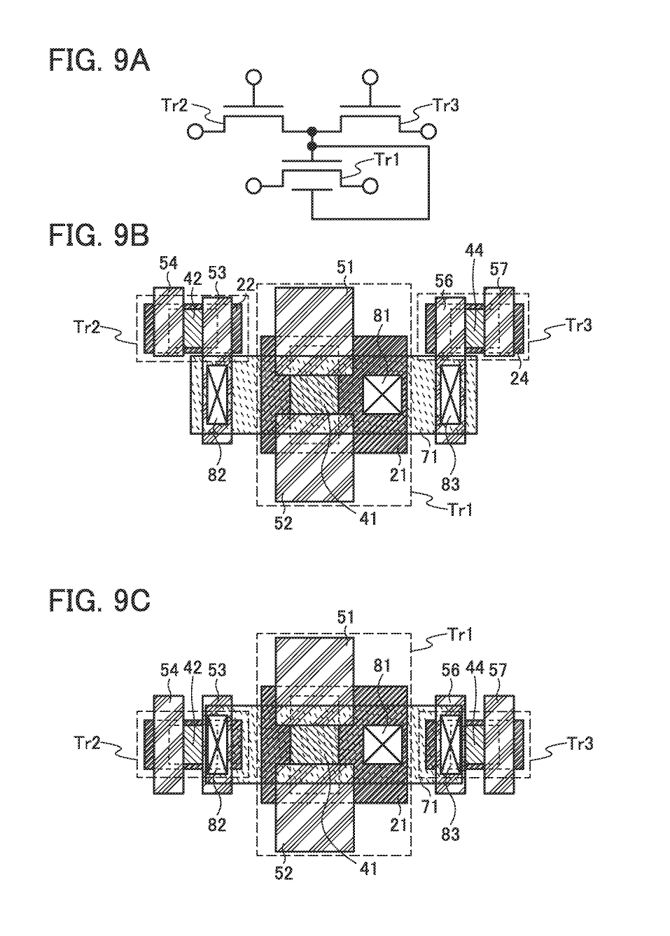

FIGS. 9A to 9C is an example in which the transistor Tr3 is added to the components in FIGS. 1A to 1C.

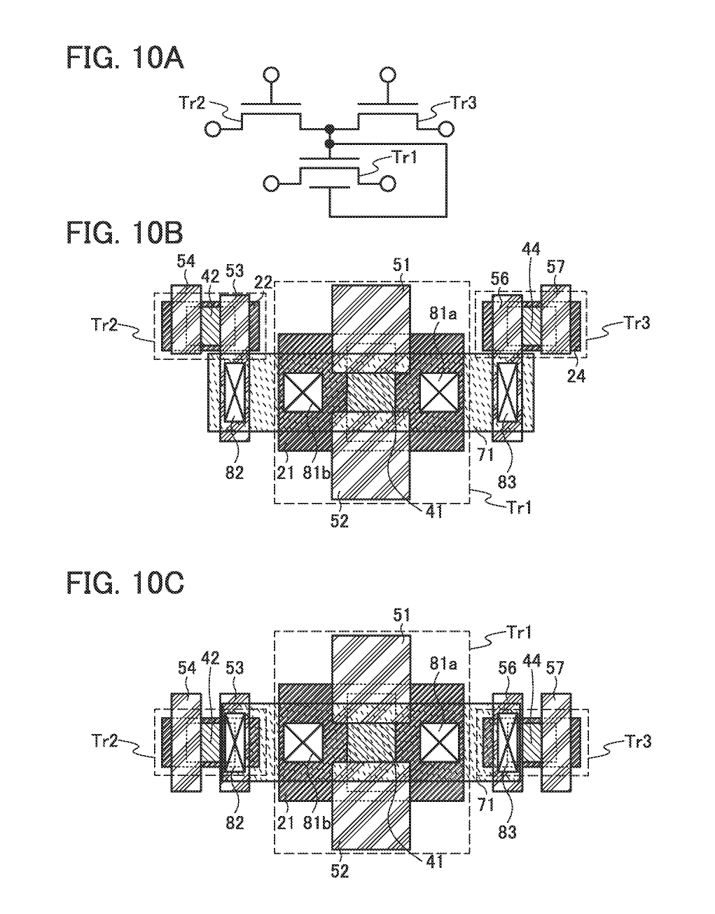

FIGS. 10A to 10C illustrate an example in which the transistor Tr3 is added to the components in FIGS. 5A to 5C.

In FIGS. 6A to 6C, FIGS. 7A to 7C, FIGS. 8A to 8C, FIGS. 9A to 9C, and FIGS. 10A to 10C, one of a source electrode and a drain electrode of the transistor Tr3 is electrically connected to the gate electrode of the transistor Tr1.

The cross sectional structures of FIGS. 6A to 6C, FIGS. 7A to 7C, FIGS. 8A to 8C, FIGS. 9A to 9C, and FIGS. 10A to 10C are similar to those in FIG. 2 and FIG. 3.

The semiconductor devices of FIGS. 6A to 6C, FIGS. 7A to 7C, FIGS. 8A to 8C, FIGS. 9A to 9C, and FIGS. 10A to 10C have the insulating layer 30 as in FIGS. 1A to 1C to FIG. 3.

The insulating layer 30 has a region capable of functioning as a gate insulating layer of the transistor Tr3.

The semiconductor devices of FIGS. 6A to 6C, FIGS. 7A to 7C, FIGS. 8A to 8C, FIGS. 9A to 9C, and FIGS. 10A to 10C each have the oxide layer 61 and the insulating layer 62 as in FIGS. 1A to 1C to FIG. 3.

It is acceptable not form the oxide layer 61.

### <FIGS. 6A to 6C, FIGS. 7A to 7C, FIGS. 8A to 8C>

In FIGS. 6A to 6C, FIGS. 7A to 7C, and FIGS. 8A to 8C, the conductive layer 23 has a region capable of serving as a gate electrode of the transistor Tr3.

In FIG. 6B, FIG. 7B, and FIG. 8B, the semiconductor layer 43 has a channel formation region of the transistor Tr3.

In each of FIG. 6C, FIG. 7C, and FIG. 8C, a semiconductor layer 4243 is provided.

The semiconductor layer 4243 has a channel formation region of the transistor Tr2.

The semiconductor layer 4243 has a channel formation region of the transistor Tr3.

The semiconductor layer 4243 has a region capable of functioning as an auxiliary line of the conductive layer 53.

For example, the top surface of the semiconductor layer 4243 is preferably in contact with the conductive layer 53.

The region capable of functioning as an auxiliary line of the conductive layer 53 overlaps with the conductive layer 53.

In FIGS. 6A to 6C, FIGS. 7A to 7C, and FIGS. 8A to 8C, the conductive layer s a region capable of functioning as the one of the source electrode and the drain electrode of the transistor Tr3.

In FIGS. 6A to 6C, FIGS. 7A to 7C, and FIGS. 8A to 8C, the conductive layer 55 has a region capable of functioning as the other of the source electrode and the drain electrode of the transistor Tr3.

For example, in FIGS. 6A to 6C, FIGS. 7A to 7C, and FIGS. 8A to 8C, the conductive layer 21, the conductive layer 22, and the conductive layer 23 can be formed through a process of etching the same conductive layer.

For example, in FIG. 6B, FIG. 7B, and FIG. 8B, the semiconductor layer 41, the semiconductor layer 42, and the semiconductor layer 43 can be formed through a process of etching the same semiconductor layer.

For example, in FIG. 6C, FIG. 7C, and FIG. 8C, the semiconductor layer 41 and the semiconductor layer 4243 can be formed through a process of etching the same semiconductor layer.

For example, in FIGS. 6A to 6C, FIGS. 7A to 7C, and FIGS. 8A to 8C, the conductive layer 51, the conductive layer 52, the conductive layer 53, the conductive layer 54, and the conductive layer 55 can be formed through a process of etching the same conductive layer.

### <FIGS. 9A to 9C and FIGS. 10A to 10C>

In FIGS. 9A to 9C and FIGS. 10A to 10C, a conductive layer 24 has a region capable of functioning as the gate electrode of the transistor Tr3.

In FIGS. 9A to 9C and FIGS. 10A to 10C, a semiconductor layer 44 has a channel formation region of the transistor Tr3.

In FIGS. 9A to 9C and FIGS. 10A to 10C, the conductive layer 56 has a region capable of functioning as the one of the source electrode and the drain electrode of the transistor Tr3.

In FIGS. 9A to 9C and FIGS. 10A to 10C, the conductive layer 57 has a region capable of functioning as the other of the source electrode and the drain electrode of the transistor Tr3.

In FIGS. 9A to 9C and FIGS. 10A to 10C, an opening 83 penetrating the oxide layer 61 and the insulating layer 62 is provided.

In FIGS. 9A to 9C and FIGS. 10A to 10C, the conductive layer 71 is electrically connected to the conductive layer 56 in the opening 83.

As illustrated in FIG. 9C and FIG. 10C, the semiconductor layer 42, the semiconductor layer 41, and the semiconductor layer 44 can be placed along the channel width direction of the transistor Tr1.

For example, the channel width direction of the transistor Tr1 can intersect with the channel length direction of the transistor Tr2 or the channel length direction of the transistor Tr3.

For example, in FIGS. 9A to 9C and FIGS. 10A to 10C, the conductive layer 21, the conductive layer 22, and the conductive layer 24 can be formed through a process of etching the same conductive layer.

For example, in FIGS. 9A to 9C and FIGS. 10A to 10C, the semiconductor layer 41, the semiconductor layer 42, and the semiconductor layer 44 can be formed through a process of etching the same semiconductor layer.

For example, in FIGS. 9A to 9C and FIGS. 10A to 10C, the conductive layer 51, the conductive layer 52, the conductive layer 53, the conductive layer 54, the conductive layer 55, the conductive layer 56, and the conductive layer 57 can be formed through a process of etching the same conductive layer.

For example, the opening 81, the opening 82, and the opening 83 can be formed through only one etching step in FIGS. 9A to 9C.

For example, the opening 81a, the opening 81b, the opening 82, and the opening 83 can be formed by only one etching step in FIGS. 10A to 10C.

The contents of Embodiments 1 to 3 can be applied to this embodiment.

### Embodiment 5

In FIGS. 1A to 1C, FIG. 2, FIG. 3, FIGS. 4A to 4C, FIGS. 5A to 5C, FIGS. 6A to 6C, FIGS. 7A to 7C, FIGS. 8A to 8C, FIGS. 9A to 9C, and FIGS. 10A to 10C, the other of the source electrode and the drain electrode of the transistor Tr2 can be electrically connected to the one of the source electrode and the drain electrode of the transistor Tr1 (In this embodiment, this connection is called a connection D).

FIGS. 1A to 11C illustrate an example of a concept that the connection D is applied to FIGS. 1A to 1C.

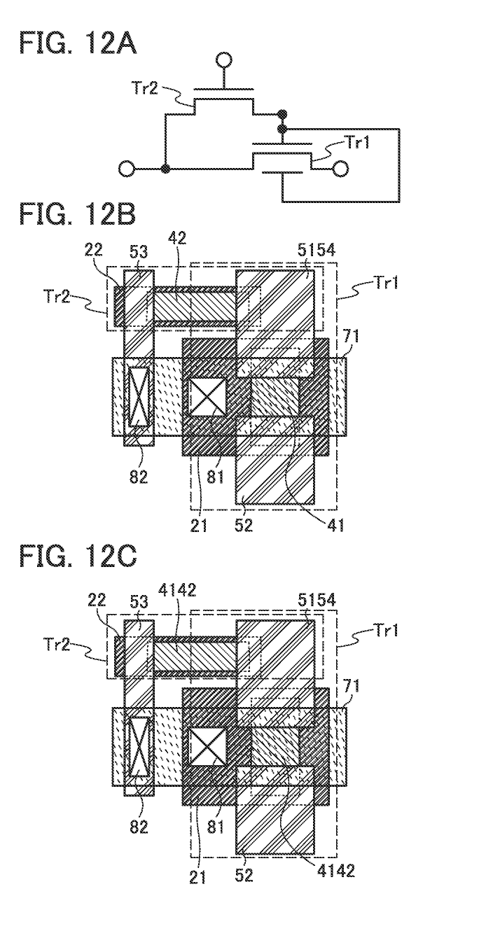

FIGS. 12A to 12C illustrate an example of a concept, hat the connection D is applied to FIGS. 4A to 4C.

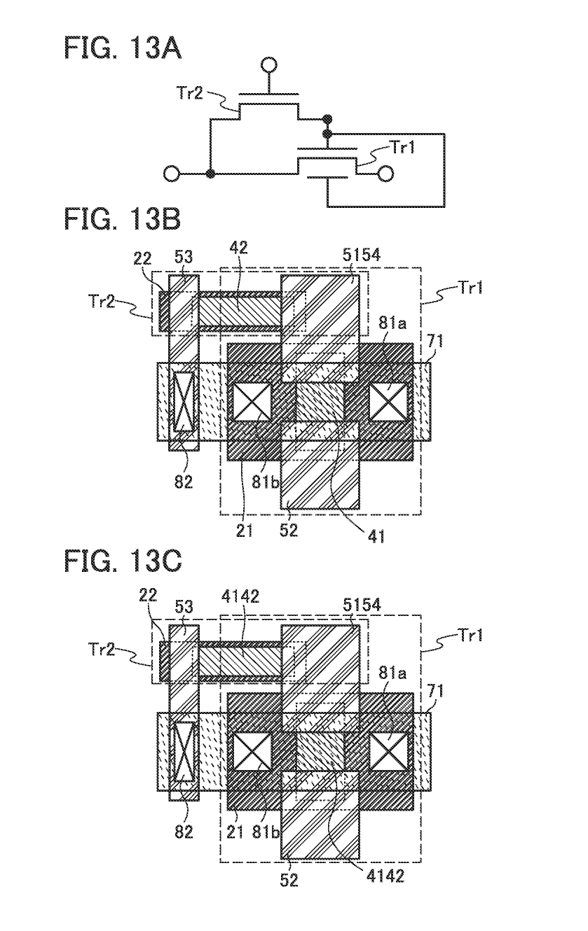

FIGS. 13A to 13C illustrate an example of a concept that the connection D is applied to FIGS. 5A to 5C.

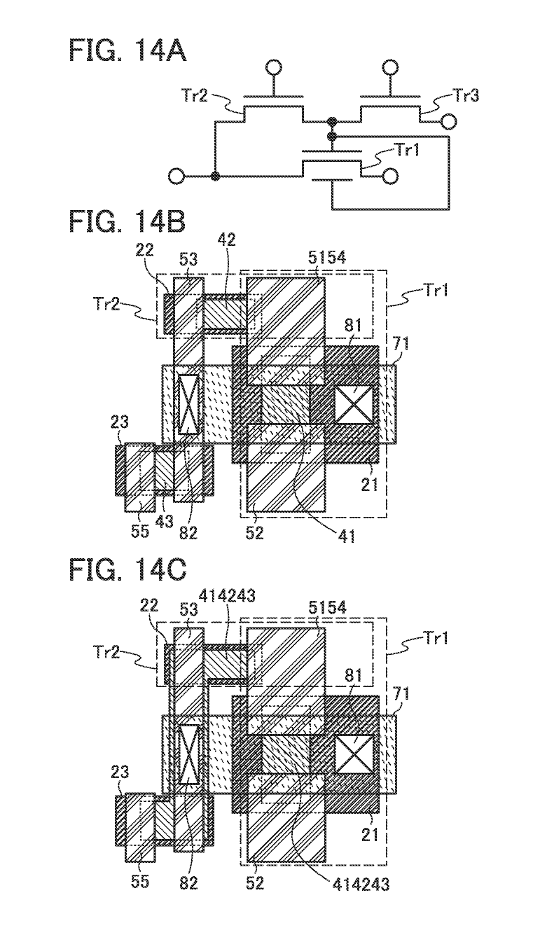

FIGS. 14A to 14C Illustrate an example of a concept that the connection D is applied to FIGS. 6A to 6C.

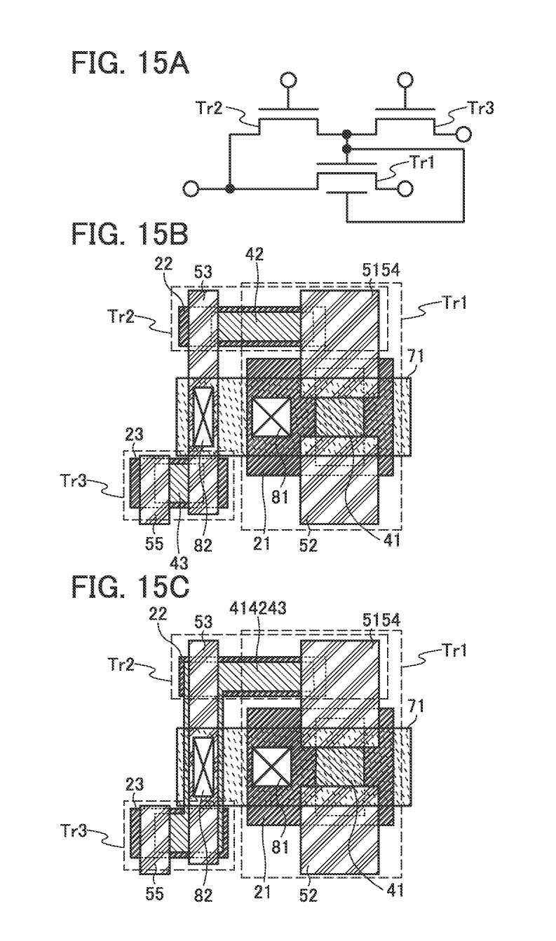

FIGS. 15A to 15C illustrate an example of a concept hat the connection D is applied to FIGS. 7A to 7C.

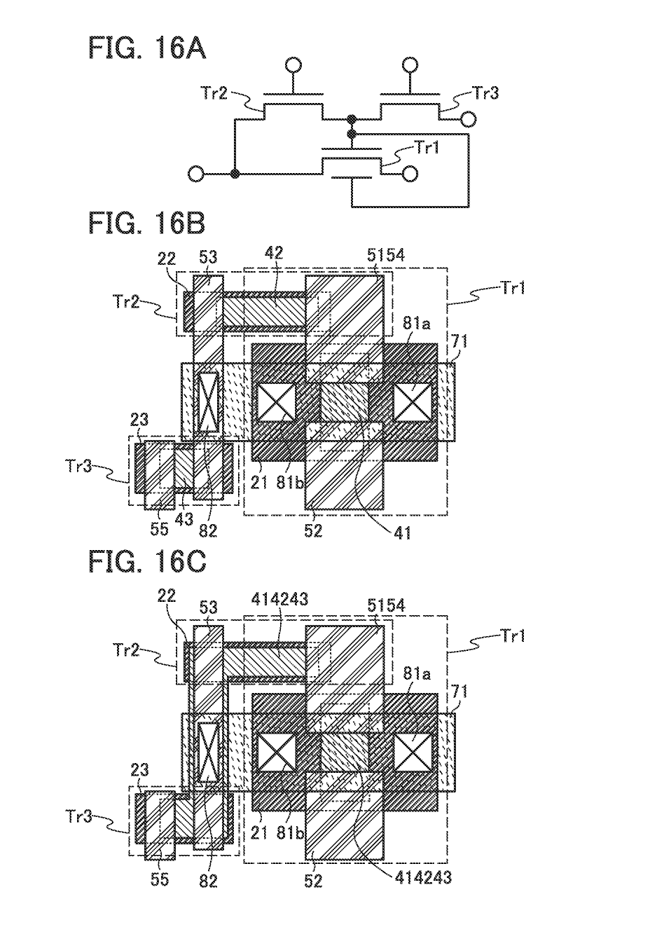

FIGS. 16A to 16C illustrate an example of a concept hat the connection D is applied to FIGS. 8A to 8C.

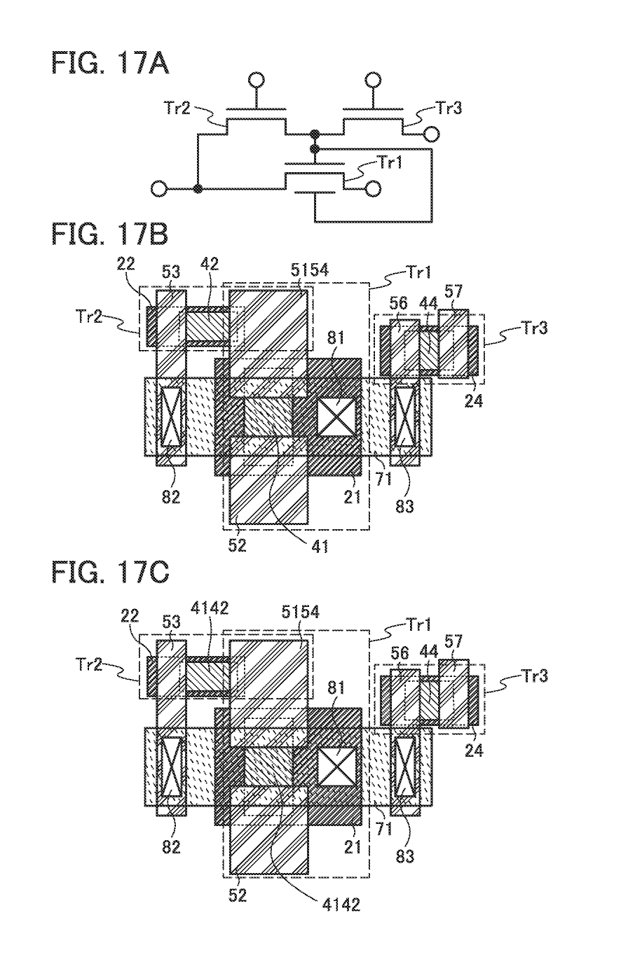

FIGS. 17A to 17C illustrate an example of a concept the connection D is applied to FIGS. 9A to 9C.

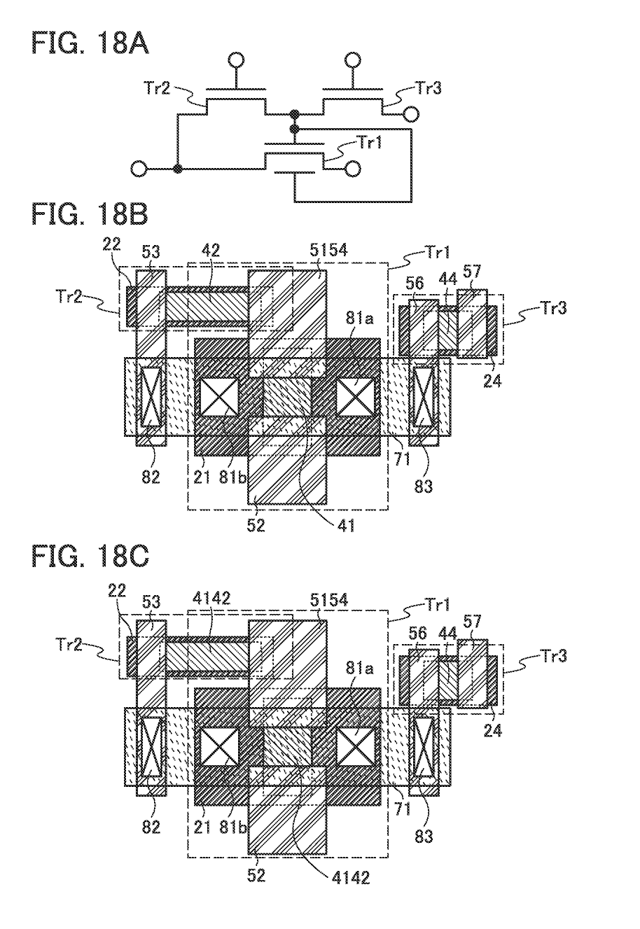

FIGS. 18A to 18C illustrate an example of a concept that the connection D is applied to FIGS. 10A to 10C.

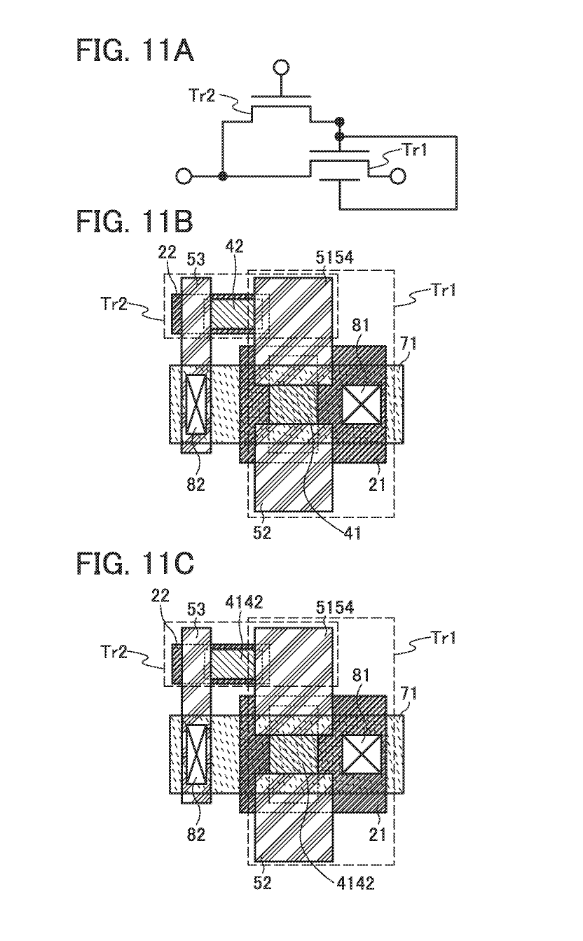

As illustrated in FIGS. 11E to 11C, FIGS. 12A to 12C, FIGS. 13A to 13C, FIGS. 14A to 14C, FIGS. 15A to 15C, FIGS. 16A to 16C, FIGS. 17A to 17C, and FIGS. 18A to 18C, a conductive layer 5154 can be used instead of the conductive layer 51 and the conductive layer 54.

In FIGS. 11A to 11C, FIGS. 12A to 12C, FIGS. 13A to 13C, FIGS. 14A to 14C, FIGS. 15A to 15C, FIGS. 16A to 16C, FIGS. 17A to 17C, and FIGS. 18A to 18C, the conductive layer 5154 has a region capable of functioning as the one of the source electrode and the drain electrode of the transistor Tr1.

In FIGS. 11A to 11C, FIGS. 12A to 12C, FIGS. 13A to 13C, FIGS. 14A to 14C, FIGS. 15A to 15C, FIGS. 16A to 16C, FIGS. 17A to 17C, and FIGS. 18A to 18C, the conductive layer 5154 has a region capable of functioning as the other of the source electrode and the drain electrode of the transistor Tr2.

As illustrated in FIG. 11C, FIG. 12C, FIG. 13C, FIG. 17C, and FIG. 18C, a semiconductor layer 4142 can be used instead of the semiconductor layer 41 and the semiconductor layer 42.

The semiconductor layer 4142 has a channel formation region of the transistor Tr1.

The semiconductor layer 4142 has a channel formation region of the transistor Tr2

The semiconductor layer 4142 has a region capable of functioning as an auxiliary line of the conductive layer 5154.

The region capable of functioning as an auxiliary line of the conductive layer 5154 overlaps with the conductive layer 5154.

As illustrated in FIG. 14C, FIG. 15C, and FIG. 16C, a semiconductor layer 414243 can be used instead of the semiconductor layer 41, the semiconductor layer 42, and the semiconductor layer 43.

The semiconductor layer 414243 has a channel formation region of the transistor Tr1.

The semiconductor layer 414243 has a channel formation region of the transistor Tr2.

The semiconductor layer 414243 has a channel formation region of the transistor Tr3

The semiconductor layer 414243 has a region capable of functioning as an auxiliary line of the conductive layer 5154.

The region capable of functioning as an at line of the conductive layer 5154 overlaps with the conductive layer 5154.

The contents of Embodiments 1 to 4 can be applied to this embodiment.

### Embodiment 6

A semiconductor device is a device having a semiconductor element.

There are no particular on the kind of the semiconductor element.

Examples of the semiconductor element include a transistor and the like

Examples of the transistor include a field effect type transistor and the like.

There are no particular limitations on the kind of the semiconductor device.

Examples of the semiconductor device includes a display device, a sensor device, a storage device, and the like.

A display device is a device having a display element.

There are no particular limitations on the kind of the display element.

Examples of the display element include an EL element (light-emitting element), a liquid crystal element, and the like.

There are no particular limitations on the kind of he display device.

Examples of the display device include an EL device (light-emitting device), a liquid crystal device, and the like.

The EL display device is a device having the EL element.

The EL element has a first electrode (for example, a pixel electrode), a second electrode (for example, a common electrode), and an EL layer.

For example, the layer is placed between the first electrode and the second electrode.

The liquid crystal display device is a device having a liquid crystal element.

The liquid crystal element has a first electrode (for example, a pixel electrode), a second electrode (for example, a common electrode), and an liquid crystal layer.

For example, the liquid crystal layer is placed between the first electrode and the second electrode.

The contents of Embodiments 1 to 5 can be applied to this embodiment.

### Embodiment 7

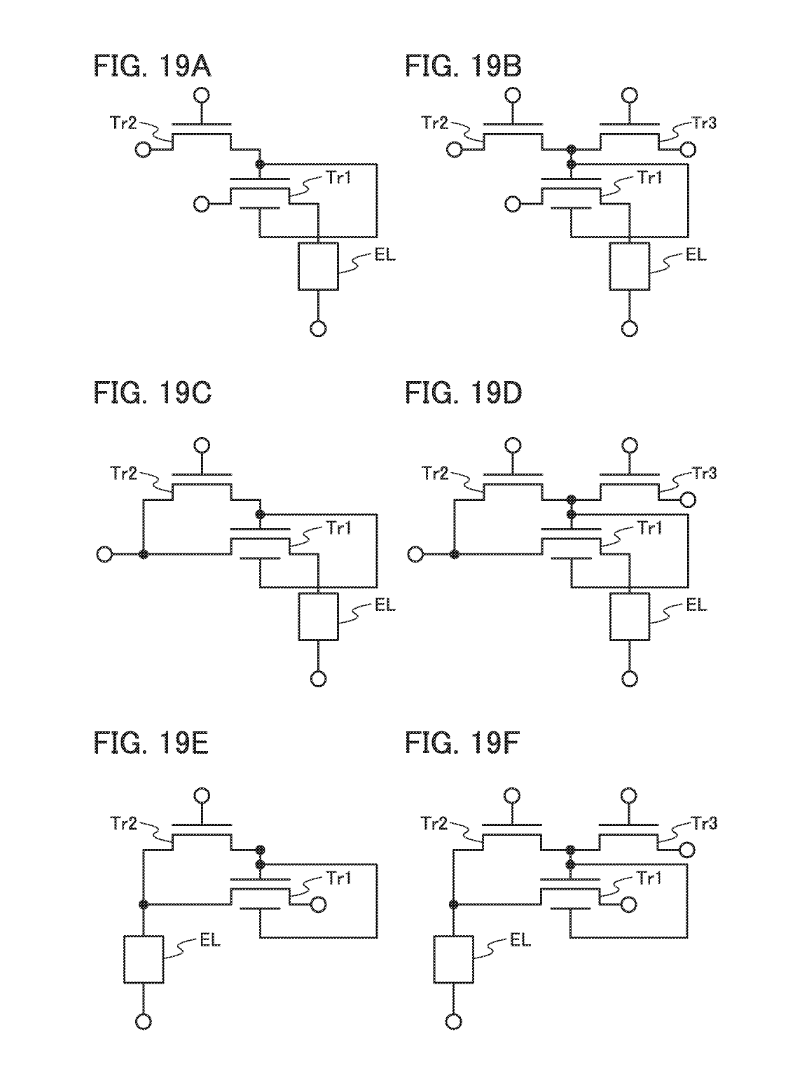

FIGS. 19A to 19F are each a pixel circuit of a display device.

In FIGS. 19A to 19F, one of the source electrode and the drain electrode of the transistor Tr2 is electrically connected to the first gate electrode of the transistor Tr1

In FIGS. 19A to 19F, the one of the source electrode and the drain electrode of the transistor Tr2 is electrically connected to the second gate electrode of the transistor Tr1

In FIGS. 19A to 19F, one of the source electrode and the drain electrode of the transistor Tr1 is electrically connected to a first electrode (a pixel electrode) of a display element EL.

For example, the display element EL is an EL element.

In FIG. 19B, FIG. 19D, and FIG. 19F, one of a source electrode and a drain electrode of a transistor Tr3 is electrically connected to the first gate electrode of the transistor Tr1.

In FIG. 19B, FIG. 19D, and FIG. 19F, the one of the source electrode and the drain electrode of the transistor Tr3 is electrically connected to the second gate electrode of the transistor Tr1.

In FIG. 19C and FIG. 19D, the other of the source electrode and the drain electrode of a transistor Tr2 is electrically connected to the other of the source electrode and the drain electrode of a transistor Tr1.

In FIG. 19E and FIG. 19F, the other of the source electrode and the drain electrode of the transistor Tr2 is electrically connected to the one of the source electrode and the drain electrode of the transistor Tr1.

In FIGS. 19A to 19F, a parasitic capacitance of the transistor Tr1 can be used as a storage capacitor.

In FIGS. 19A to 19F, a capacitor having a function of a storage capacitor can be electrically connected to the first gate electrode of the transistor Tr1.

For example, electrical current is supplied to the display element EL through the transistor Tr1.

For example, a video signal can be written by turning on the transistor Tr2.

In particular, for example, the variations in the threshold voltage of the transistor Tr1 can be corrected by turning on the transistor Tr2 in FIGS. 19C to 19F.

For example, a video signal can be reset by turning on the transistor Tr3.

For example, the polarity of transistor Tr1 in FIGS. 19C and 19D is reverse to the polarity of transistor Tr1 in FIGS. 19E and 19F.

The contents of Embodiments 1 to 6 can be applied to this embodiment.

### Embodiment 8

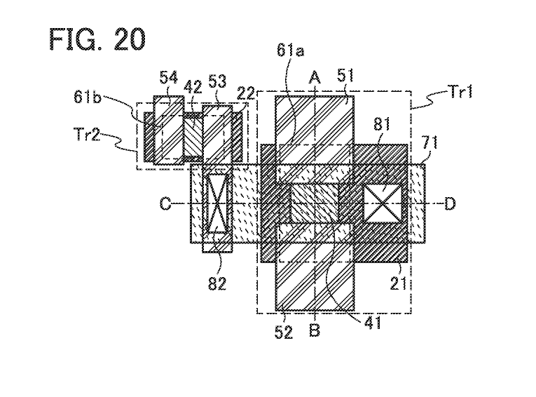

FIG. 20 to FIG. 22 each illustrate an example of a semiconductor device.

The oxide layer 61 preferably has an island-shape.

For example, as in FIG. 20, an oxide layer 61a and an oxide layer 61b can be used instead of the oxide layer 61.

Because FIG. 20 is similar to FIG. 1B, the explanation thereof is not repeated.

In FIG. 20, the shapes of the oxide layer 61a and the oxide layer 61b are each shown by a broken line.

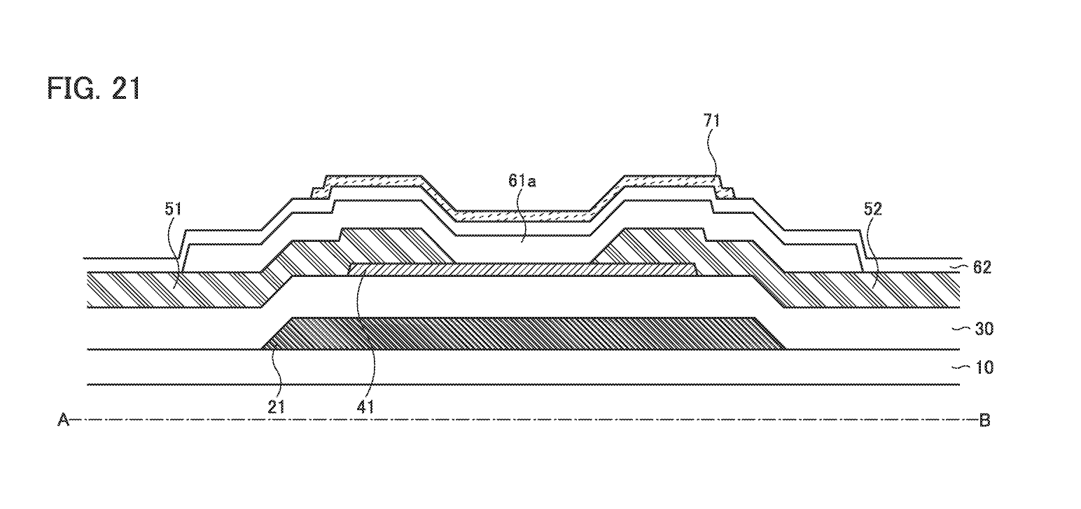

FIG. 21 is an example of the cross section taken along the line A-B in FIG. 20.

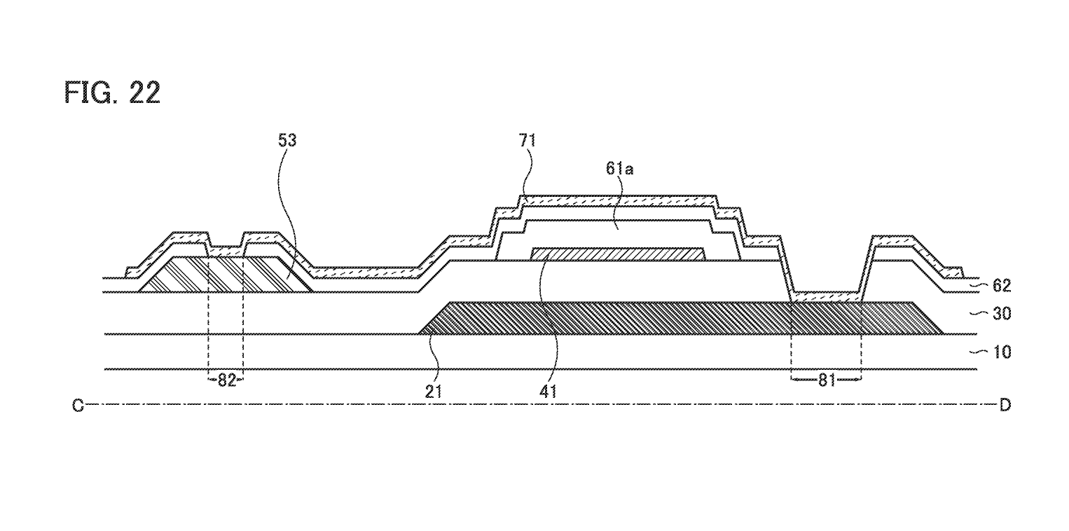

FIG. 22 is an example of the cross section taken along the line C-D in FIG. 20.

Because the oxide layer 61a covers the semiconductor layer 41, the oxide layer 61a has a region being in contact with a top surface and a side surface of the semiconductor layer 41.

The conductive layer 21 has a first region overlapping with the oxide layer 61a.

The conductive layer 21 has a second region not overlapping with the oxide layer 61a between the oxide layer 61a and the opening 81.

The conductive layer 21 has a third region not overlapping with the oxide layer 61a between the oxide layer 61a and the opening 82.

The first region is located between the second region and the third region.

Because each of the second region and the third region overlaps with the conductive layer 71, the conductive layer 71 is close to the side surface of the semiconductor layer 41.

Because the conductive layer 71 is close to the side surface of the semiconductor layer 41, the amount of carriers flowing in the side surface of the semiconductor layer 41 is increased.

Because the oxide layer 61b covers the semiconductor layer 42, the oxide layer 61b has a region being in contact with a top surface and a side surface of the semiconductor layer 42.

The conductive layer 22 has a region overlapping with the oxide layer 61b.

The conductive layer 22 has a region not overlapping with the oxide layer 61b.

It is possible that the conductive layer 22 does not have a region not overlapping with the oxide layer 61b.

The electrical property of the transistor becomes worse because of hydrogen contained in an oxide semiconductor layer.

If hydrogen is contained in the insulating layer 62, it is preferable for the semiconductor layer 41 not to be in contact with in the insulating layer 62.

If hydrogen is contained in the insulating layer 62, it is preferable for the semiconductor layer 42 not to be in contact with in the insulating layer 62.

The contents of Embodiments 1 to 7 can be applied to this embodiment.

### Embodiment 9

For example, in FIGS. 1A to 1C, FIG. 2, and FIG. 3, the etching time for forming the opening 81 is longer than the etching time for forming the opening 82.

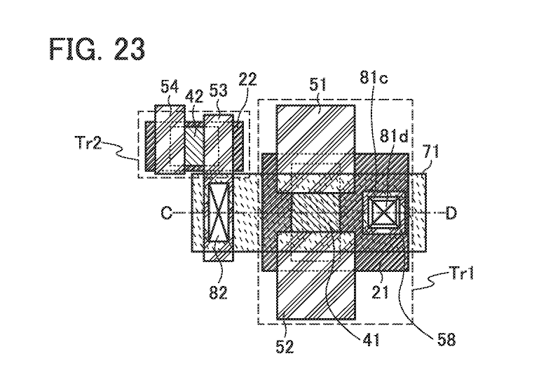

For example, when a conductive layer 58 is used as illustrated in FIG. 23 to FIG. 26, the etching time for forming the opening Si is equal to the etching time for forming the opening 82.

In FIG. 23 to FIG. 26, an etching process becomes easy as compared with FIGS. 1A to 1C, FIG. 2. and FIG. 3.

Because FIG. 23 is similar to FIG. 1B, the explanation thereof is not repeated.

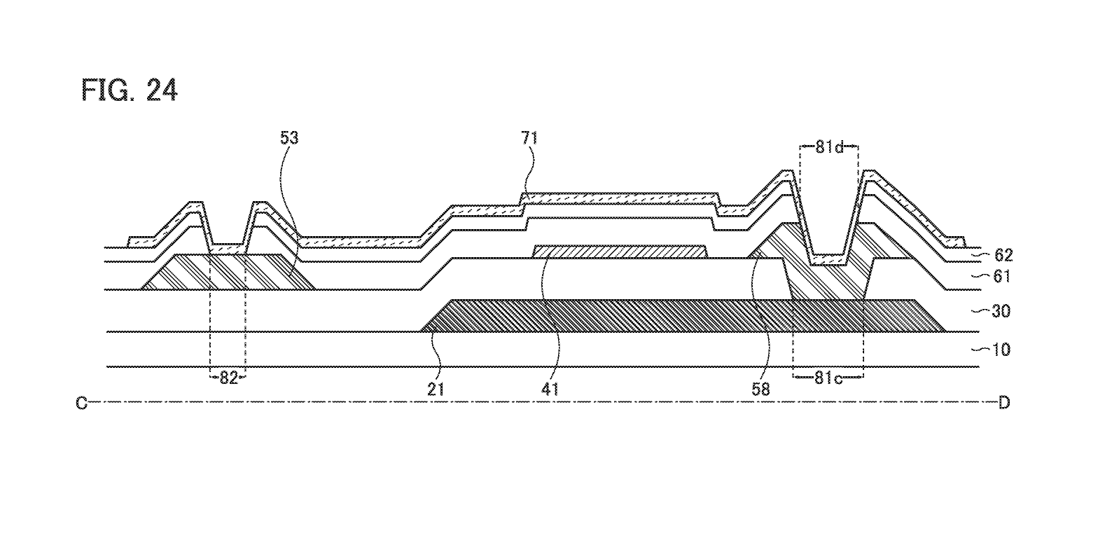

FIG. 24 is an example of the cross section taken along the line C-D in FIG. 23.

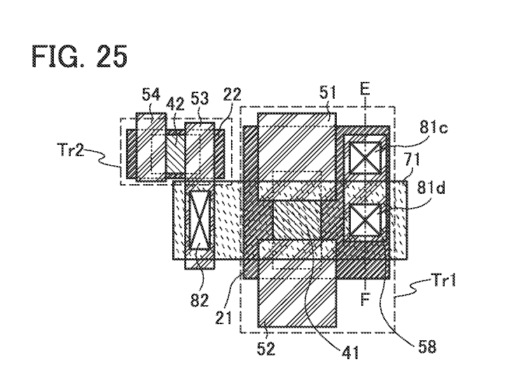

Because FIG. 25 is similar to FIG. 1B, the explanation thereof is not repeated.

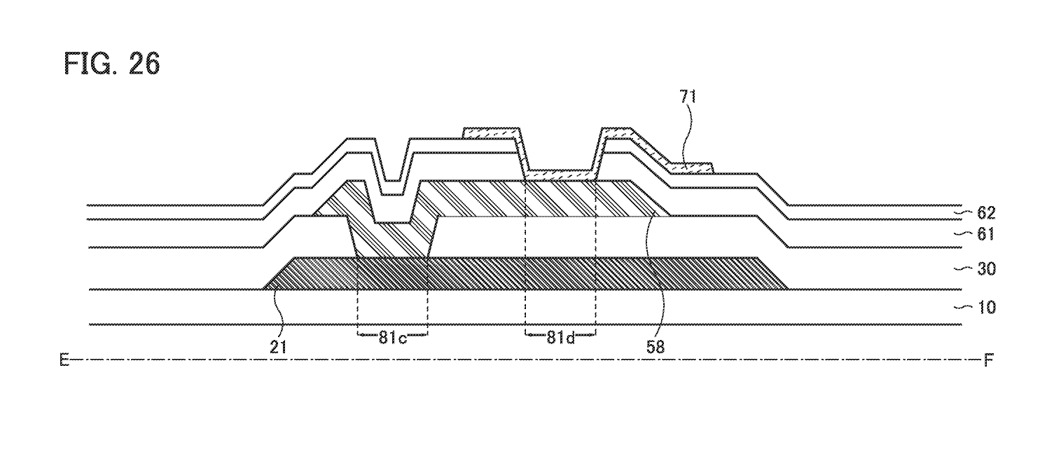

FIG. 26 is an example of the cross section taken along the line F-F in FIG. 25.

The insulating layer 30 has an opening 81c.

The oxide layer 61 and the insulating layer 62 have an opening 81d.

The opening 81d has an opening formed in the oxide layer 61 and an opening formed in the insulating layer 62.

The conductive layer 58 is electrically connected to the conductive 21 in the opening 81c.

The conductive layer 71 is electrically connected to the conductive layer 58 in the opening 81d.

The conductive layer 71 is electrically connected to the conductive layer 53 in the opening 82.

For example, the conductive layer 51, the conductive layer .52, the conductive layer 53, the conductive layer 54, and the conductive layer 58 can be formed through a process of etching the same conductive layer.

For example, the opening 81d and the opening 82 can be formed by only etching step.

In FIG. 23 and FIG. 24, the opening 81d have a region overlapping with the opening 81c.

In FIG. 25 and FIG. 26, because the opening 81d does not overlap with the opening 81c, a disconnection of the conductive layer 71 can be prevented.

The contents of Embodiments 1 to 8 can be applied to this embodiment.

### Embodiment 10

The materials of the substrate and layers are described.

Of course, the materials of the substrate and layers are not limited to those exemplified in this embodiment.

### <Layer>

For example, a layer is a single film or a stacked film.

The single film includes one film.

The stacked films include plural films.

For example, the stacked films have at least a first film and a second film.

For example, the material of the first film is different from that of the second film.

For example, the material of the first film is the same as that of the second film.

For example, each of the first film and the second film can be selected from the films exemplified in this embodiment.

### <Materials>

For example, the substrate can be a glass substrate, a plastic substrate, and a metal substrate, or the like.

For example, the conductive layer includes a layer having metal or a layer having oxide conductor.

For example, the conductive layer may include only the layer having metal.

For example, the conductive layer may include only the layer having oxide conductor.

For example, the conductive layer includes the layer having metal and the layer having oxide conductor.

For example, the metal can be selected from aluminum, gold, silver, copper, tungsten, titanium, molybdenum, chromium, niobium, nickel, cobalt, and the like.

Examples of layer having metal include a metal film, an alloy film, and a metal nitride film.

For example, the oxide conductor can be selected from indium tin oxide (ITO), indium tin oxide containing silicon, and indium zinc oxide, and the like.

For example, the oxide conductor has a light-transmission property.

For example, the first electrode (pixel electrode) or the second electrode (common electrode) has a light-transmission property.

For example, the first electrode (pixel electrode) or the second electrode (common electrode) includes ITO.

For example, the oxide layer includes an oxide semiconductor layer or an oxide insulating layer.

For example, the oxide layer may include only the oxide semiconductor layer.

For example, the oxide layer may include only the oxide insulating layer.

For example, the oxide layer may include the oxide insulating layer and the oxide semiconductor layer.

For example, the oxide layer may include the oxide semiconductor layer over the oxide insulating layer.

For example, the oxide layer may include the oxide semiconductor layer under the oxide insulating layer.

For example, the insulating layer has an oxide insulating layer, a nitride insulating layer, or an organic insulating layer.

For example, the semiconductor layer has an oxide semiconductor layer or a silicon semiconductor layer.

The oxide insulating layer is a layer having an oxide insulator.

For example, the oxide insulator can be selected from the following: silicon oxide, aluminum oxide, gallium oxide, and the like.

For example, the oxide insulator an contain nitrogen.

The nitride insulating layer is a layer having a nitride insulator.

For example, the nitride insulator can be selected from the following: silicon nitride, aluminum nitride, gallium nitride, and the like.

For example, the nitride insulator contain oxygen.

The organic insulating layer is a layer having an organic insulator.

For example, the organic insulator can be selected from the following: acrylic, polyimide, siloxane, and the like.

The oxide semiconductor layer is a layer having an oxide semiconductor.

The silicon semiconductor layer is a layer having a silicon semiconductor.

For example, the silicon semiconductor can be selected from the following: silicon, silicon gallium, silicon carbide, and the like.

<Oxide semiconductor>

For example, the oxide semiconductor has indium (In), tin (Sn), zinc (Zn), or gallium (Ga).

For example, the oxide semiconductor can be selected from the following: indium oxide, tin oxide, zinc oxide, and the like.

For example, the oxide semiconductor can be selected from the following: indium zinc oxide, zinc tin oxide, and the like.

For example, as the oxide semiconductor, an oxide having In, an element M, and Zn can be used.

For example, the element M can be selected from typical metals, transition metals, and the like.

For example, the typical metal can be Ga, Al, Sn, and the like.

For example, the transition metal can be Ti, Hf, lanthanoid, actinoid, and the like.

### <C Axis Aligned Crystal (CAAC)>

Because the oxide semiconductor layer has a c-axis-aligned crystalline (CAAC) region along the direction X, the density of the oxide semiconductor layer is increased.

By the increased density of the oxide semiconductor layer, H₂O can be prevented from entering the oxide semiconductor layer.

For example, the direction X is a direction perpendicular to the surface of the oxide semiconductor layer.

For example, the angle between the c axis and the surface of the oxide semiconductor layer is 90 degrees.

For example, the direction X is a direction that is substantially perpendicular to the surface of the oxide semiconductor layer.

For example, the angle between the c axis and the surface of the oxide semiconductor layer is from 80 degrees to 100 degrees.

A crystalline region whose c-axis is aligned with the direction X is called a CAAC region.

### <Stacked Films>

It is of interest that the oxide semiconductor layer has stacked films.

Defects exist at the interface between the oxide semiconductor layer and the insulating layer.

In particular, when the insulating layer or the oxide semiconductor layer contains silicon, more defects tend to exist at the interface between the oxide semiconductor layer and the insulating layer.

The reliability of the transistor is improved by distancing its channel from such defects.

The oxide semiconductor layer having particular stacked films can enable a channel to be located away from the interface between the oxide semiconductor layer and the insulating layer.

For example, the oxide semiconductor layer has an oxide semiconductor film A and an oxide semiconductor film B.

For example, e semiconductor film B is placed over the oxide semiconductor film A.

For example, the oxide semiconductor film B is placed under the oxide semiconductor film A.

For example, each of the oxide semiconductor film A and the oxide semiconductor film B has indium (In), gallium (Ga), and zinc (Zn).

For example, the oxide semiconductor layer has the oxide semiconductor film A, the oxide semiconductor film B, and an oxide semiconductor film C.

For example, the oxide semiconductor film B is placed over the oxide semiconductor film A.

For example, the oxide semiconductor film C is placed under the oxide semiconductor film A.

For example, each of the oxide semiconductor film A, the oxide semiconductor film B, and the oxide semiconductor film C has indium (In), gallium (Ga), and zinc (Zn).

For example, the proportion of gallium contained in the oxide semiconductor film B is preferably high.

For example, the proportion of zinc contained in the oxide semiconductor film B is preferably high.

For example, the proportion of gallium contained in the oxide semiconductor film C is preferably high.

For example, the proportion of zinc contained in the oxide semiconductor film C is preferably high.

For example, “(the ratio of gallium to indium contained in the oxide semiconductor film B)” is higher than “(the ratio of gallium to indium contained in the oxide semiconductor film A)”.

For example, “(the ratio of zinc to indium contained in the oxide semiconductor film B)” is higher than “(the ratio of zinc to indium contained in the oxide semiconductor film A)”.

For example, “(the ratio of gallium to indium contained in the oxide semiconductor film C)” is higher than “(the ratio of gallium to indium contained in the oxide semiconductor film A)”.

For example, “(the ratio of zinc to indium container the oxide semiconductor film C)” is higher than “(the ratio of zinc to indium contained in the oxide semiconductor film A)”.

For example, in the oxide semiconductor film A, the element M can be used instead of Ga.

For example, in the oxide semiconductor film B, the element M can be used instead of Ga.

For example, in the oxide semiconductor film C, the element M can be used instead of Ga.

For example, the element M can be any of metals described in this embodiment.

When the proportion of indium contained in the oxide semiconductor film is low, the band gap of the oxide semiconductor film is large.

When the proportion of indium contained in the oxide semiconductor film is high, the band gap of the oxide semiconductor film is small.

When the oxide semiconductor layer includes stacked films, a channel is formed in an oxide semiconductor film having the smallest band gap.

For example, when the oxide semiconductor layer includes the oxide semiconductor film A and the oxide semiconductor film B, a channel is formed in the oxide semiconductor film A.

For example, when the oxide semiconductor layer includes the oxide semiconductor film A, the oxide semiconductor film B, and the oxide semiconductor film C, a channel is formed in the oxide semiconductor film A.

The channel formed in the oxide semiconductor film A is apart from defects.

For example, the oxide semiconductor film A includes a CAAC region.

For example, the crystallinity of the oxide semiconductor film B or the oxide semiconductor film C is lower than that of the oxide semiconductor film A.

For example, a metal impurity such as nickel, copper, or cobalt moves into a low-crystalline region from a high-crystalline region.

When the crystallinity of the oxide semiconductor film B or the oxide semiconductor film C is lower than that of the oxide semiconductor film A, such a metal impurity is gettered by the oxide semiconductor film B or the oxide semiconductor film C.

In other words, gettering of the metal impurity from the channel can be performed.

The crystallinity can be confirmed, for example, by the degree of clarity of electron diffraction patterns (spots).

For example, clear electron diffraction spots indicate high crystallinity.

For example, unclear electron diffraction spots indicate low crystallinity.

With results by electron diffraction of two films, clarity can be compared.

In addition, the oxide layer can be, for example, an oxide semiconductor layer having a band gap larger than that of an oxide semiconductor layer having a channel formation region.

The contents of embodiments 1 to 9 can be applied to this embodiment.

This application is based on Japanese Patent Application serial no. 2013-128068 filed with Japan Patent Office on Jun. 19, 2013, the entire contents of which are hereby incorporated by reference.

What is claimed is:

1. A semiconductor device comprising:
a first conductive layer;
a first insulating layer over the first conductive layer;
an oxide semiconductor layer over the first insulating layer;
a second conductive layer electrically connected to the oxide semiconductor layer;
a third conductive layer electrically connected to the oxide semiconductor layer;
a fourth conductive layer over the first insulating layer;
a second insulating layer over the oxide semiconductor layer, the second conductive layer, the third conductive layer, and the fourth conductive layer; and
a fifth conductive layer over the second insulating layer,
wherein the first insulating layer includes a first opening,
wherein the second insulating layer includes a second opening and a third opening,
wherein the fifth conductive layer is electrically connected to the first conductive layer via the first opening and the second opening,
wherein the fifth conductive layer is electrically connected to the e fourth conductive layer via the third opening,
wherein the fourth conductive layer includes a first region capable of functioning as one of a source electrode and a drain electrode of a first transistor, wherein the oxide semiconductor layer includes a second region overlapping with the first conductive layer, and
wherein the fifth conductive layer overlaps with the second region.

2. The semiconductor device according to claim 1, further comprising an oxide layer between the oxide semiconductor layer and the second insulating layer,
wherein the first conductive layer includes a third region not overlapping with the oxide layer, and
wherein the fifth conductive layer includes a fourth region overlapping with the third region.

3. The semiconductor device according to claim 1, wherein the first opening, the oxide semiconductor layer, and the third opening are placed along a channel width direction of a second transistor comprising the oxide semiconductor layer.

4. The semiconductor device according to claim 1, wherein a channel length direction of the first transistor is in a direction substantially perpendicular to a channel length direction of a second transistor comprising the oxide semiconductor layer.

5. The semiconductor device according to claim 1, wherein a longer direction of the fifth conductive layer is in a direction substantially perpendicular to a channel length direction of a second transistor comprising the oxide semiconductor layer.

6. A semiconductor device comprising:
a first conductive layer;
a first insulating layer over the first conductive layer;
an oxide semiconductor layer over the first insulating layer;
a second conductive layer electrically connected to the oxide semiconductor layer;
a third conductive layer electrically connected to the oxide semiconductor layer;
a fourth conductive layer over the first insulating layer;
a sixth conductive layer over the first insulating layer;
a second insulating layer over the oxide semiconductor layer, the second conductive layer, the third conductive layer, and the fourth conductive layer; and
a fifth conductive layer over the second insulating layer,
wherein the first insulating layer includes a first opening,
wherein the second insulating layer includes a second opening and a third opening,
wherein the sixth conductive layer is electrically connected to the first conductive layer via the first opening,
wherein the fifth conductive layer is electrically connected to the sixth conductive layer via the second opening,
wherein the fifth conductive layer is electrically connected to the e fourth conductive layer via the third opening,
wherein the fourth conductive layer includes a first region capable of functioning as one of a source electrode and a drain electrode of a first transistor,
wherein the oxide semiconductor layer includes a second region overlapping with the first conductive layer, and
wherein the fifth conductive layer overlaps with the second region.

7. The semiconductor device according to claim 6, further comprising an oxide layer between the oxide semiconductor layer and the second insulating layer,
wherein the first conductive layer includes a third region not overlapping with the oxide layer, and
wherein the fifth conductive layer includes a fourth region overlapping with the third region.

8. The semiconductor device according to claim 6, wherein the first opening, the oxide semiconductor layer, and the third opening are placed along a channel width direction of a second transistor comprising the oxide semiconductor layer.

9. The semiconductor device according to claim 6, wherein a channel length direction of the first transistor is in a direction substantially perpendicular to a channel length direction of a second transistor comprising the oxide semiconductor layer.

10. The semiconductor device according to claim 6, wherein a longer direction of the fifth conductive layer is in a direction substantially perpendicular to a channel length direction of a second transistor comprising the oxide semiconductor layer.

11. The semiconductor device according to claim 6, wherein the second opening does not overlap with the first opening.

12. A semiconductor device comprising:
a first conductive layer;
a first insulating layer over the first conductive layer;
a semiconductor layer over the first insulating layer;
a second conductive layer electrically connected to the semiconductor layer;
a third conductive layer electrically connected to the semiconductor layer;
a fourth conductive layer over the first insulating layer;
a second insulating layer over the semiconductor layer, the second conductive layer, the third conductive layer, and the fourth conductive layer; and
a fifth conductive layer over the second insulating layer,
wherein the first insulating layer includes a first opening,
wherein the second insulating layer includes a second opening and a third opening,
wherein the fifth conductive layer is electrically connected to the first conductive layer via the first opening and the second opening,
wherein the fifth conductive layer is electrically connected to the fourth conductive layer via the third opening,
wherein the fourth conductive layer includes a first region capable of functioning as one of a source electrode and a drain electrode of a first transistor, and
wherein the semiconductor layer includes a second region overlapping with the first conductive layer, and
wherein the fifth conductive layer overlaps with the second region.

13. The semiconductor device according to claim 12, further comprising an oxide layer between the semiconductor layer and the second insulating layer,
wherein the first conductive layer includes a third region not overlapping with the oxide layer, and
wherein the fifth conductive layer includes a fourth region overlapping with the third region.

14. The semiconductor device according to claim 12, wherein the first opening, the semiconductor layer, and the third opening are placed along a channel width direction of a second transistor comprising the semiconductor layer.

15. The semiconductor device according to claim 12, wherein a channel length direction of the first transistor is in a direction substantially perpendicular to a channel length direction of a second transistor comprising the semiconductor layer.

16. The semiconductor device according to claim 12, wherein a longer direction of the fifth conductive layer is in a direction substantially perpendicular to a channel length direction of a second transistor comprising the semiconductor layer.
